(19) United States
(12) Patent Application Publication
(10) Pub. No.: US 2008/0231476 A1
(43) Pub. Date: Sep. 25, 2008

(54) RISER, RIDGE BASED TOUCH KEYPAD FOR PORTABLE ELECTRONIC DEVICE

(76) Inventor: YUNG-LUNG LIU, Ta Ya Shiang (TW)

Correspondence Address: G. LINK CO., LTD., 3550 BELL ROAD, MINOOKA, IL, 60447, US

(21) Appl. No.: 11/687,669

(22) Filed: Mar. 19, 2007

(51) Int. Cl. H03K 17/94

(52) U.S. Cl. 341/20; 341/27

(57) ABSTRACT

A riser, ridge based touch keypad for a portable electronic device (e.g., mobile phone or flex pointer) is disclosed such that either in a dark environment a person with good eyesight or a person with decreased visual acuity may feel the riser(s) and the ridges representing a unique pattern with the finger in order to find the desired hidden key associated with the unique pattern prior to pressing. A couple of embodiments are also disclosed.

### BACKGROUND OF THE INVENTION

1. Field of Invention

The invention relates to touch equipment, and more particularly to a riser, ridge based touch keypad for a portable electronic device (e.g., mobile phone or flex pointer) with improved characteristics.

2. Description of Related Art

Conventionally, a mobile phone or flex pointer is equipped with a plurality of keys arranged in rows and columns on its top surface. These keys are either function keys or keys of an alphanumeric keypad. As the trend of minimizing the occupying space of a portable electronic device (e.g., mobile phone or flex pointer), so the area of the keys becomes smaller. Hence, senior citizens or those with decreased visual acuity may find it difficult of using such devices due to poor eyesight. Further, people may find it difficult of using such devices in a dark environment. Thus, a need for improvement exists.

### SUMMARY OF THE INVENTION

It is therefore one object of the invention to provide a riser, ridge based touch keypad for a portable electronic device (e.g., mobile phone or flex pointer) such that either in a dark environment a person with good eyesight or a person with decreased visual acuity may feel the riser(s) and the ridges representing a unique pattern with the finger in order to find the desired key associated with the unique pattern prior to pressing.

In one aspect of the invention there is provided a touch keypad mountable on a portable electronic device comprising a flexible touch panel including a longitudinal rail raised along either side of a top surface the electronic device, either rail including a plurality of projections of different lengths extending transversely toward a longitudinal center line of the electronic device, each projection having one or more raised parallel ridges arranged as a unique pattern, a plurality of hidden keys formed under the top surface of the electronic device, and a plurality of pegs each integrally formed with the hidden key and projecting downward; and a film circuit board mounted under the touch panel and including a plurality of top terminals each disposed under the peg by a predetermined distance, whereby in a typing operation feeling the patterns with the finger by the guidance of the rails and the ridges to find the desired projection, and pressing the hidden key immediately adjacent the desired projection will cause the peg under the pressed hidden key to contact the terminal to send an electrical signal representing the pressed hidden key to a processor of the electronic device for processing.

In another aspect of the invention there is provided a touch keypad mountable on a portable electronic device comprising a flexible touch panel including a longitudinal rail raised along a center line of a top surface the electronic device, the rail including a plurality of projections of different lengths extending transversely from either side, each projection having one or more raised parallel ridges arranged as a unique pattern, and a plurality of hidden keys formed under the top surface of the electronic device; and capacitive sensing means mounted under the touch panel and including two conductive layers each having a plurality of sensor zones, and an insulative layer sandwiched between the conductive layers, wherein each sensor zone of the upper conductive layer is aligned with the hidden key and is spaced apart by a predetermined distance, and the sensor zones of the upper conductive layer are aligned with the sensor zones of the lower conductive layer, whereby in a typing operation feeling the patterns with the finger by the guidance of the rails and the ridges to find the desired projection, and pressing the hidden key immediately adjacent the desired projection will change a capacitance between the pressed hidden key and the sensor zone of the upper conductive layer and send an electrical signal representing the pressed hidden key to a processor of the electronic device for processing.

The above and other objects, features and advantages of the invention will become apparent from the following detailed description taken with the accompanying drawings.

### BRIEF DESCRIPTION OF THE DRAWINGS

FIG. 1 is a perspective view of a mobile phone incorporating a first preferred embodiment of touch keypad according to the invention;

FIG. 2 is an exploded view of touch panel and film circuit board of the touch keypad shown in FIG. 1;

FIG. 3 is a sectional view taken along line 3-3 of FIG. 1 showing alignment of hidden key and terminal for effecting a correct finger pressing;

FIG. 4 is a perspective view of a flex pointer incorporating a second preferred embodiment of touch keypad according to the invention; and

FIG. 5 is a sectional view taken along line 5-5 of FIG. 4 showing alignment of key and sensor zone for effecting a correct finger pressing.

### DETAILED DESCRIPTION OF THE INVENTION

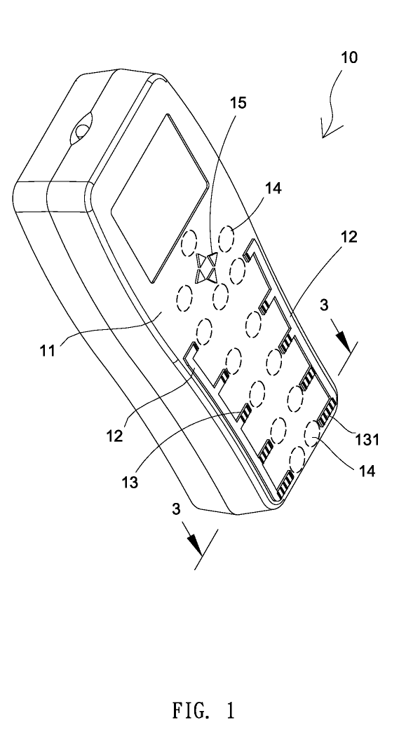

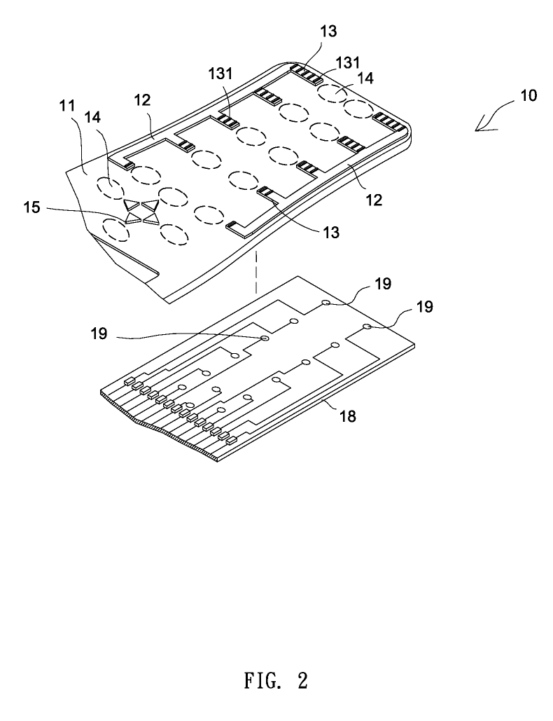

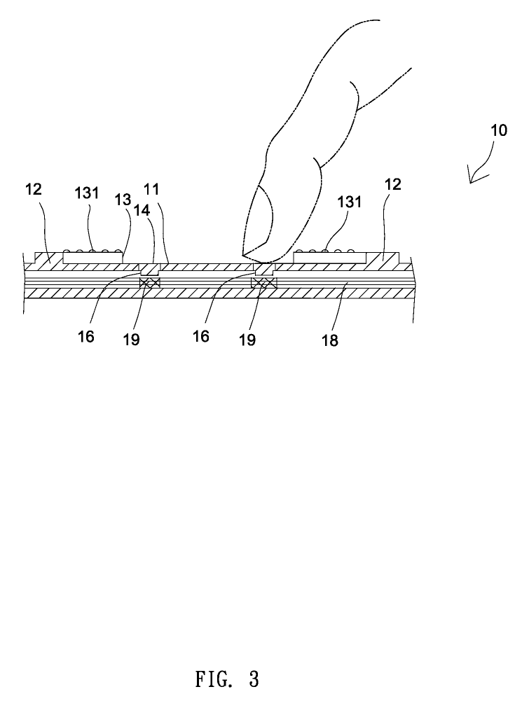

Referring to FIGS. 1 to 3, a mobile phone incorporating a first preferred embodiment of touch keypad 10 according to the invention is shown. The touch keypad 10 comprises a thin touch panel 11 and an underlying film circuit board 18. Each component is discussed in detailed below.

The touch panel 11 is formed of thermoplastic material and comprises a longitudinal rail 12 along either side of the mobile phone. The rail 12 has a length of about half of the height of the mobile phone in an upright position. The rail 12 raises a predetermined distance from a top surface of the mobile phone. The rail 12 comprises a plurality of (five are shown) short projections 13 extending transversely toward the other rail 12. The projections 13 extending from the same rail 12 are of different lengths. The projection 13 has one or more raised parallel ridges 131 arranged as a pattern which is adapted to feel by the finger. The rail 12 may shape as a curve or an oblique line other than the shown straight line in other embodiments.

A plurality of circular flat hidden keys 14 are formed under the top surface of the mobile phone and are defined between a display (not numbered) and the rails 12. A plurality of projecting pegs 16 each is integrally formed with the hidden key 14 and projects downward. A plurality of (four representing top, down, left, and right) raised function keys 15 of triangle are formed between the display and the rails 12. Each function key 15 is associated with a specific hidden key 14 disposed adjacent therewith.

The film circuit board 18 is comprised of a plurality of thin layers laminated together. The film circuit board 18 comprises a plurality of terminals 19 on a top surface. Each terminal 19 is disposed under the corresponding peg 16 by a short predetermined distance.

An operation of the invention will be described in detailed below. Either in a dark environment a visually good person or a person with decreased visual acuity may feel the patterns (i.e., the ridges 131) with the finger. For example, the front left projection 13 representing numeral “0” is the key to be pressed. Thus, the person may press the hidden key 14 immediately adjacent the front left projection 13 by the guidance of the left rail 12 and the ridges 131 (see FIG. 1). And in turn, the peg 16 under the pressed hidden key 14 contacts the corresponding terminal 19. As such, an electrical circuit is temporarily formed and an electrical signal representing the numeral “0” is sent to a microprocessor of the mobile phone for processing. This completes a single operation of typing.

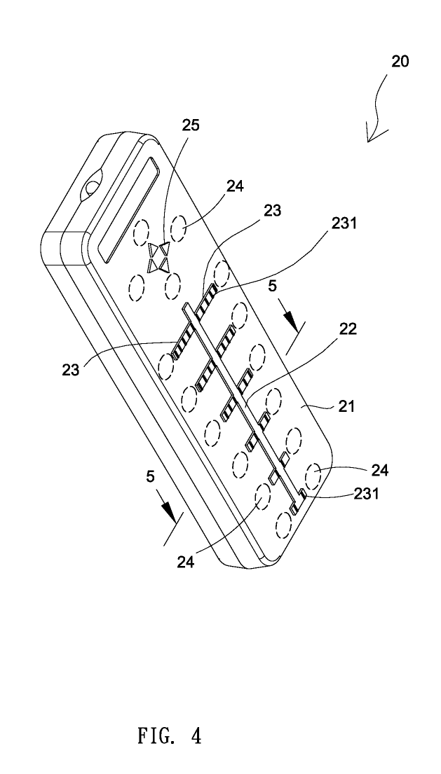

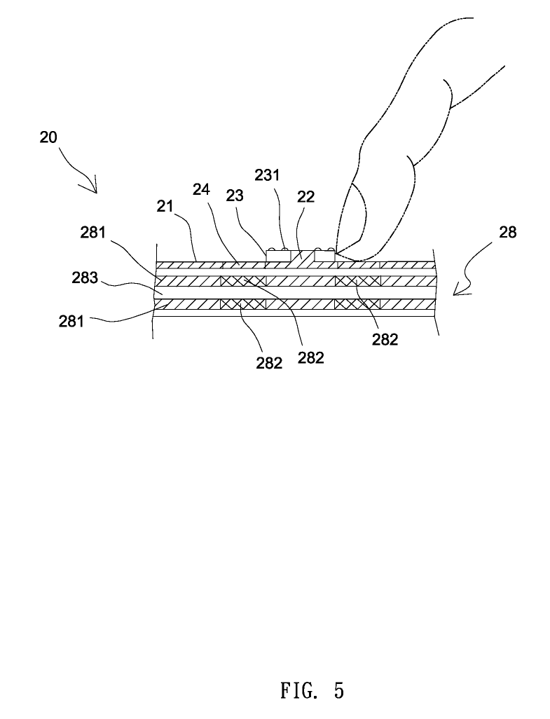

Referring to FIGS. 4 and 5, a mobile phone incorporating a second preferred embodiment of touch keypad 20 according to the invention is shown. The touch keypad 20 comprises a thin touch panel 21 and an underlying capacitive sensing member 28. Each component is discussed in detailed below.

The touch panel 21 is formed of thermoplastic material and comprises a longitudinal rail 22 along a center line of the flex pointer. The rail 22 has a length of more than half of the height of the flex pointer in an upright position. The rail 22 raises a predetermined distance from a top surface of the flex pointer. The rail 22 comprises a plurality of (five are shown) short projections 23 extending transversely from either side. The projections 23 extending from the same side of the rail 22 are of different lengths. The projection 23 has one or more raised parallel ridges 231 arranged as a pattern which is adapted to feel by the finger. The rail 22 may shape as a curve or an oblique line other than the shown straight line in other embodiments.

A plurality of circular flat hidden keys 24 are formed under the top surface of the flex pointer and each is located immediately adjacent an open end of the projection 23. A plurality of (four representing top, down, left, and right) raised function keys 25 of triangle are formed between a front end of the flex pointer and the rail 22. Each function key 25 is associated with a specific hidden key 24 disposed adjacent therewith.

The capacitive sensing member 28 is capacitive and is comprised of two conductive layers 281 and an insulative layer 283 sandwiched therebetween. A plurality of sensor zones 282 are formed in each conductive layer 281. Each sensor zone 282 is aligned with an underside of the hidden key 24 and is spaced apart by a short predetermined distance. Also, the sensor zones 282 of the upper conductive layer 281 are aligned with the sensor zones 282 of the lower conductive layer 281.

An operation of the invention will be described in detailed below. Either in a dark environment a visually good person or a person with decreased visual acuity may feel the patterns (i.e., the ridges 231) with the finger. For example, the front left projection 23 representing numeral “0” is the key to be pressed. Thus, the person may press the hidden key 24 immediately adjacent the front left projection 23 by the guidance of the rail 22 and the ridges 231 (see FIG. 4). And in turn, a capacitance between the pressed hidden key 24 and the sensor zone 282 of the upper conductive layer 281 thereunder changes due to a distance change therebetween. As such, an electrical circuit is temporarily formed and an electrical signal representing the numeral “0” is sent to a microprocessor of the mobile phone for processing. This completes a single operation of typing.

The invention has additional advantages as below. Its resolution is high, i.e., high sensitivity in typing operation. Further, it is small and lightweight and can meet the trend of miniaturization.

While the invention herein disclosed has been described by means of specific embodiments, numerous modifications and variations could be made thereto by those skilled in the art without departing from the scope and spirit of the invention set forth in the claims.

What is claimed is:

1. A touch keypad mountable on a portable electronic device comprising:
a flexible touch panel including a longitudinal rail raised along either side of a top surface the electronic device, either rail including a plurality of projections of different lengths extending transversely toward a longitudinal center line of the electronic device, each projection having one or more raised parallel ridges arranged as a unique pattern, a plurality of hidden keys formed under the top surface of the electronic device, and a plurality of pegs each integrally formed with the hidden key and projecting downward; and
a film circuit board mounted under the touch panel and including a plurality of top terminals each disposed under the peg by a predetermined distance,
whereby in a typing operation feeling the patterns with the finger by the guidance of the rails and the ridges to find the desired projection, and pressing the hidden key immediately adjacent the desired projection will cause the peg under the pressed hidden key to contact the terminal to send an electrical signal representing the pressed hidden key to a processor of the electronic device for processing.

2. The touch keypad of claim 1, wherein the touch panel is formed of thermoplastics.

3. The touch keypad of claim 1, further comprising a plurality of raised function keys of triangle, each function key being associated with a corresponding one of the hidden keys adjacent therewith.

4. The touch keypad of claim 1, wherein the electronic device is a mobile phone or a flex pointer.

5. The touch keypad of claim 1, wherein either rail is straight, curve, or oblique.

6. A touch keypad mountable on a portable electronic device comprising:
a flexible touch panel including a longitudinal rail raised along a center line of a top surface the electronic device, the rail including a plurality of projections of different lengths extending transversely from either side, each projection having one or more raised parallel ridges arranged as a unique pattern, and a plurality of hidden keys formed under the top surface of the electronic device; and
capacitive sensing means mounted under the touch panel and including two conductive layers each having a plurality of sensor zones, and an insulative layer sandwiched between the conductive layers, wherein each sensor zone of the upper conductive layer is aligned with the hidden key and is spaced apart by a predetermined distance, and the sensor zones of the upper conductive layer are aligned with the sensor zones of the lower conductive layer,
whereby in a typing operation feeling the patterns with the finger by the guidance of the rails and the ridges to find the desired projection, and pressing the hidden key immediately adjacent the desired projection will change a capacitance between the pressed hidden key and the sensor zone of the upper conductive layer and send an electrical signal representing the pressed hidden key to a processor of the electronic device for processing.

7. The touch keypad of claim 6, wherein the touch panel is formed of thermoplastics.

8. The touch keypad of claim 6, further comprising a plurality of raised function keys of triangle, each function key being associated with a corresponding one of the hidden keys adjacent therewith.

9. The touch keypad of claim 6, wherein the electronic device is a mobile phone or a flex pointer.

10. The touch keypad of claim 6, wherein the rail is straight, curve, or oblique.
